(19) United States
(12) Patent Application Publication
(10) Pub. No.: US 2010/0206846 A1
(43) Pub. Date: Aug. 19, 2010

(54) SUBSTRATE PROCESSING APPARATUS AND SUBSTRATE PROCESSING METHOD

(75) Inventors: Eiichi Nishimura, Nirasaki-shi (JP); Masato Morishima, Nirasaki-shi (JP); Morihiro Takanashi, Nirasaki-shi (JP); Akitaka Shimizu, Nirasaki-shi (JP); Yuichi Setsuhara, Suita-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: TOKYO ELECTRON LIMITED, Tokyo (JP); Osaka University, Suita-shi (JP)

(21) Appl. No.: 12/706,094

(22) Filed: Feb. 16, 2010

Related U.S. Application Data
(60) Provisional application No. 61/178,532, filed on May 15, 2009.

(30) Foreign Application Priority Data
Feb. 17, 2009 (JP) 2009-033851

(51) Int. Cl. C23F 1/08; C23C 16/00; C23C 16/505; C23F 1/00

(52) U.S. Cl. 216/67; 118/723 I; 156/345.48; 427/569

(57) ABSTRACT

A substrate processing apparatus that can appropriately carry out desired plasma processing on a substrate. The substrate is accommodated in an accommodating chamber. An ion trap partitions the accommodating chamber into a plasma producing chamber and a substrate processing chamber. High-frequency antennas are disposed in the plasma producing chamber. A process gas is introduced into the plasma producing chamber. The substrate is mounted on a mounting stage disposed in the substrate processing chamber, and a bias voltage is applied to the mounting stage. The ion trap has grounded conductors and insulating materials covering surfaces of the conductors.

### BACKGROUND OF THE INVENTION

1. Field of the Invention

The present invention relates to a substrate processing apparatus and a substrate processing method, and a substrate processing apparatus and a substrate processing method that use plasma produced using high-frequency antennas.

2. Description of the Related Art

As substrate processing apparatuses that subject a wafer as a substrate to processing using plasma such as CVD processing and plasma processing, there are known a substrate processing apparatus that produces and uses capacitively-coupled plasma, a substrate processing apparatus that produces and uses inductively-coupled plasma, a substrate processing apparatus that produces and uses ECR (electron cyclotron resonance) plasma, and a substrate processing apparatus that produces and uses microwave plasma. Each of these apparatuses has an accommodating chamber in which a wafer is accommodated and subjected to processing using plasma.

Among those mentioned above, the substrate processing apparatus that uses inductively-coupled plasma has high-frequency antennas in the accommodating chamber so as to efficiently use high-frequency electrical power when producing plasma (see, for example, Japanese Laid-Open Patent Publication (Kokai) No. 2007-220600). In this substrate processing apparatus, high-density plasma, for example, plasma with an ion concentration of about 10¹⁰ cm⁻³ to 10¹¹ cm⁻³ can be easily obtained.

However, when the density of plasma produced in the accommodating chamber increases, the intensity of ultraviolet light emitted from the plasma increases, which may adversely affect a film formed on a wafer. Also, with increase in plasma density, the number of ions attracted to a wafer mounted on a mounting stage to which a bias voltage is applied increases, which may cause various films formed on a wafer to excessively wear in a specific direction due to sputtering. Namely, if high-density plasma produced by the high-frequency antennas is used as it is, desired plasma processing could not be appropriately carried out on a wafer.

### SUMMARY OF THE INVENTION

The present invention provides a substrate processing apparatus and a substrate processing method that can appropriately carry out desired plasma processing on a substrate.

Accordingly, in a first aspect of the present invention, there is provided a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, and a mounting stage that is disposed in the substrate processing chamber, and on which the substrate is mounted and to which a bias voltage is applied, wherein the partition member comprises grounded conductors and insulating materials covering surfaces of the conductors.

According to the first aspect of the present invention, because the partition member partitions the accommodating chamber into the plasma producing chamber and the substrate processing chamber, ultraviolet light emitted from high-density plasma produced in the plasma producing chamber toward the substrate processing chamber can be blocked, so that the intensity of ultraviolet light reaching the substrate can be decreased. Moreover, the partition member has the insulating materials covering the surfaces of the conductors, and hence when plasma produced in the plasma producing chamber moves toward the substrate processing chamber, first, electrons are charged to the insulating materials, and the major portion of ions in the plasma are attracted to the electrons, so that a sheath is produced in the vicinity of the partition member. Namely, because the major portion of ions in the plasma is collected in the vicinity of the partition member, the number of ions attracted to the substrate mounted on the mounting stage to which a bias voltage is applied can be reduced. As a result, radicals in the plasma can be preferentially caused to reach the substrate. Further, because the partition member has the grounded conductors, the partition member can act as an opposing electrode for the mounting stage to which a bias voltage is applied and which acts as an electrode, and positively produce an electric field in the substrate processing chamber. As a result, desired plasma processing can be appropriately carried out on the substrate.

The first aspect of the present invention can provide a substrate processing apparatus, wherein the partition member comprises plate-like members that are at least doubly disposed from the plasma producing chamber toward the substrate processing chamber, and the plate-like members comprise insulating materials covering surfaces.

According to the first aspect of the present invention, because the partition member is comprised of the plate-like members that are at least doubly disposed from the plasma producing chamber toward the substrate processing chamber, ultraviolet light emitted from high-density plasma produced in the plasma producing chamber toward the substrate processing chamber can be positively blocked, and moreover, because each plate-like member has an insulating material covering a surface thereof, each plate-like member can attract ions, and hence a large amount of ions in the plasma can be positively prevented from passing through the partition member.

The first aspect of the present invention can provide a substrate processing apparatus, wherein the plate-like members comprise a plurality of through holes penetrating the plate-like members in a superposing direction, and when viewed from the plasma producing chamber toward the substrate processing chamber, the through holes of one of the plate-like members do not overlap the through holes of the other one of the plate-like members.

According to the first aspect of the present invention, because each plate-like member has a plurality of through holes penetrating the plate-like member in a superposing direction, plasma can pass through the partition member from the plasma producing chamber toward the substrate processing chamber, but when viewed from the plasma producing chamber toward the substrate processing chamber, the through holes of one plate-like member do not overlap the through holes of the other plate-like member, and hence ions linearly moving from the plasma producing chamber toward the substrate processing chamber, due to a bias voltage cannot pass through the partition member. As a result, radicals in the plasma can be preferentially caused to reach the substrate mounted on the mounting stage in the substrate processing chamber.

The first aspect of the present invention can provide a substrate processing apparatus further comprising another process gas introducing unit that introduces another process gas into the substrate processing chamber.

According to the first aspect of the present invention, because there is also the other process gas introducing unit that introduces the other process gas into the substrate processing chamber, the substrate can be subjected to not only plasma processing but also processing using the other process gas, and thus processing variations can be increased.

The first aspect of the present invention can provide a substrate processing apparatus, wherein the other process gas introducing unit comprises a plurality of gas outlets, and the plurality of gas outlets are disposed at dispersed locations on the substrate processing chamber side of the partition member.

According to the first aspect of the present invention, because the plurality of gas outlets are disposed at dispersed locations on the substrate processing chamber side of the partition member, other process gas can be introduced into the substrate processing chamber in a dispersed manner, and as a result, processing using other process gas can be uniformly carried out on the substrate.

The first aspect of the present invention can provide a substrate processing apparatus, wherein a distance between the high-frequency antennas and the partition member is 30 mm or more.

According to the first aspect of the present invention, because the distance between the high-frequency antennas and the partition member is 30 mm or more, the partition member can be prevented from inhibiting the formation of a magnetic field produced from the high-frequency antennas, and as a result, plasma can be efficiently produced in the plasma producing chamber.

Accordingly, in a second aspect of the present invention, there is provided a substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, a mounting stage that is disposed in the substrate processing chamber, and on which the substrate is mounted and to which a bias voltage is applied, and another process gas introducing unit that produces another process gas into the substrate processing chamber, the partition member comprising grounded conductors and insulating materials covering surfaces of the conductors, comprising a raw gas introducing step in which the other process gas introducing unit introduces a silane-based gas into the substrate processing chamber, and a plasma producing step in which the process gas introducing unit introduces oxygen gas into the plasma producing chamber, and the high-frequency antennas produce plasma from the oxygen gas.

According to the second aspect of the present invention, because in the substrate processing apparatus that blocks ultraviolet light emitted from high-density plasma produced in the plasma producing chamber, and reduces the number of ions attracted to the substrate to cause radicals to preferentially reach the substrate, a silane-based gas is introduced into the substrate processing chamber, and then plasma is produced from the oxygen gas in the plasma producing chamber, oxygen radicals preferentially reach the substrate after the silane-based gas is attracted to the surface of the substrate. As a result, a silicon dioxide film can be positively formed on the surface of the wafer through a chemical reaction of silicon in the silane-based gas and the oxygen radicals while various films formed on the wafer are prevented from deteriorating due to ultraviolet light and wearing due to ion sputtering.

Accordingly, in a third aspect of the present invention, there is provided a substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, and a mounting stage that is disposed in the substrate processing chamber, and on which the substrate is mounted and to which a bias voltage is applied, the partition member comprising grounded conductors and insulating materials covering surfaces of the conductors, comprising a plasma producing step in which the process gas introducing unit introduces hydrogen gas into the plasma producing chamber, and the high-frequency antennas produce plasma from the hydrogen gas, wherein foreign matter is deposited on at least a part of a surface of the substrate.

According to the third aspect of the present invention, because in the substrate processing apparatus that blocks ultraviolet light emitted from high-density plasma produced in the plasma producing chamber, and reduces the number of ions attracted to the substrate to preferentially cause radicals to reach the substrate, the plasma is produced from the hydrogen gas in the plasma producing chamber, hydrogen radicals can be preferentially caused to reach the substrate on at least a part of the surface of which foreign matter is deposited, and the deposited foreign matter can be preferentially caused to chemically react with the hydrogen radicals without being sputtered with ions. Thus, only foreign matter deposited on at least a part of the surface of the substrate can be removed while wear of other films formed from substances that do not react with the hydrogen radicals is prevented.

Accordingly, in a fourth aspect of the present invention, there is provided a substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, and a mounting stage that is disposed in the substrate processing chamber, and on which the substrate is mounted and to which a bias voltage is applied, the partition member comprising grounded conductors and insulating materials covering surfaces of the conductors, comprising a plasma producing step in which the process gas introducing unit introduces oxygen gas into the plasma producing chamber, and the high-frequency antennas produce plasma from the oxygen gas, wherein the substrate has on a surface thereof a projection that comprises a photoresist and having a predetermined width.

According to the fourth aspect of the present invention, because in the substrate processing apparatus that blocks ultraviolet light emitted from high-density plasma produced in the plasma producing chamber, and reduces the number of ions attracted to the substrate to preferentially cause radicals to reach the substrate, the plasma is produced from the oxygen gas in the plasma producing chamber, oxygen radicals can be preferentially caused to reach the substrate on the projection comprised of the photoresist having the predetermined width is formed, and the photoresist can be preferentially caused to chemically react with the oxygen radicals without being sputtered with ions. When developed, the texture on the side surface of the projection comprised of the photoresist becomes chemically weak. Thus, the side surface of the projection is selectively etched through the chemical reaction with the radicals. As a result, the width of the projection can be reduced without making the height of the projection too small.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing a construction of a substrate processing apparatus according to an embodiment of the present embodiment;

FIG. 2 is a partial enlargement cross-sectional view schematically showing a construction of an ion trap appearing in FIG. 1;

FIGS. 3A to 3C are process drawings showing a film formation method as a substrate processing method according to the present embodiment;

FIGS. 4A to 4E are process drawings showing a dry cleaning method as a substrate processing method according to the present embodiment; and

FIGS. 5A to 5C are process drawings showing a trimming method as a substrate processing method according to the present embodiment.

### DETAILED DESCRIPTION OF PREFERRED EMBODIMENTS

The present invention will now be described in detail with reference to the drawings showing a preferred embodiment thereof.

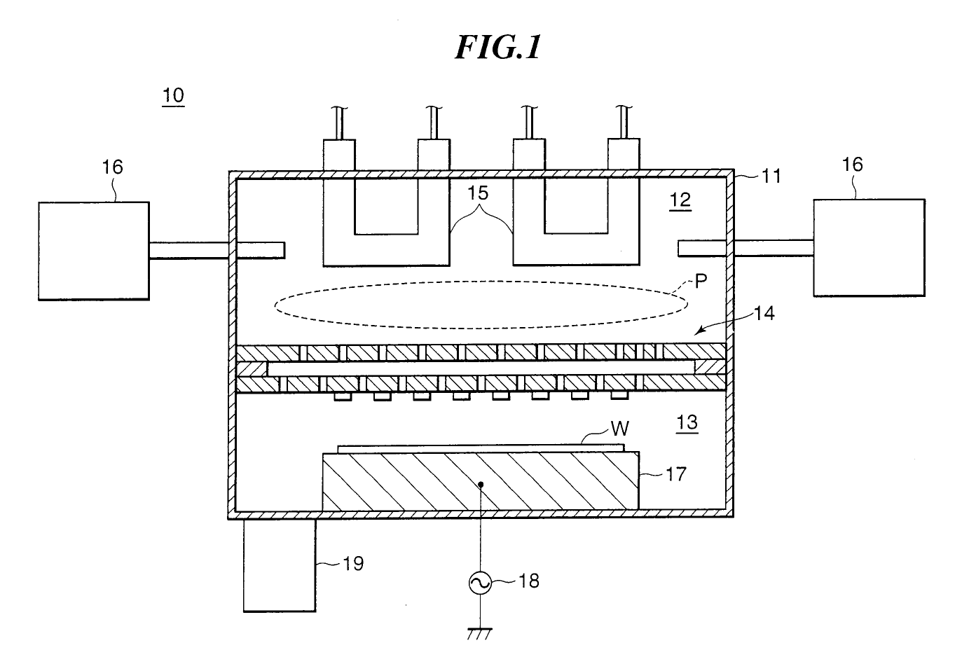

FIG. 1 is a cross-sectional view schematically showing a construction of a substrate processing apparatus according to the present embodiment.

Referring to FIG. 1, the substrate processing apparatus 10 has a substantially cylindrical chamber 11 (accommodating chamber) in which a semiconductor wafer (hereinafter referred to merely as a “wafer”) W is accommodated, an ion trap (partition member) 14 that is disposed such as to partition the interior of the chamber 11 into two in the direction of height, i.e. a plasma producing chamber 12 and a wafer processing chamber 13, a plurality of high-frequency antennas 15 disposed in the plasma producing chamber 12, a process gas introducing unit 16 that introduces a process gas introduced into the plasma producing chamber 12, a mounting stage 17 that is disposed in the wafer processing chamber 13 such as to face the ion trap 14, a high-frequency power source 18 that applies a bias voltage to the mounting stage 17, and an exhausting unit 19 that evacuates the interior of the wafer processing chamber 13 and adjusts pressure.

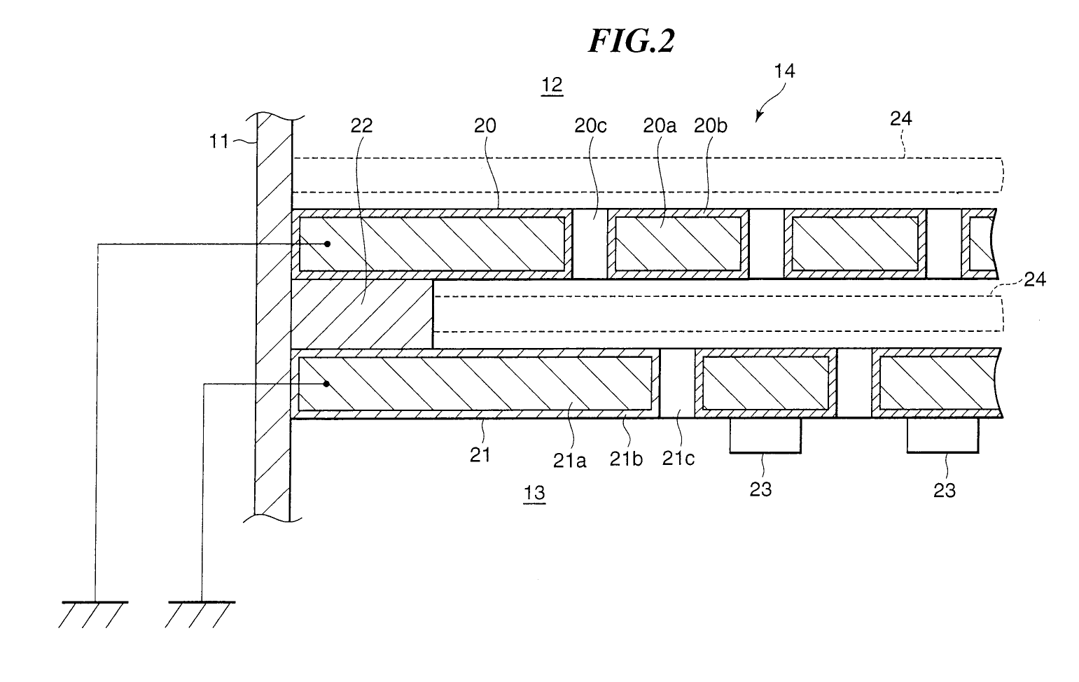

FIG. 2 is a partial enlargement cross-sectional view schematically showing the construction of the ion trap appearing in FIG. 1.

Referring to FIG. 2, the ion trap 14 is comprised of an upper ion trap plate 20 (one plate-like member) and a lower ion trap plate 21 (the other plate-like member), which are doubly disposed from the plasma producing chamber 12 toward the wafer processing chamber 13, and a spacer 22 that maintains the interval between the upper ion trap plate 20 and the lower ion trap plate 21 at a predetermined value. The upper ion trap plate 20 and the lower ion trap plate 21 have conductive materials 20a and 21a, respectively, insulating films 20b and 21b, respectively, comprised of insulating materials covering the surfaces of the conductors 20a and 21a, and a plurality of through holes 20c and 21c that penetrate the upper ion trap plate 20 and the lower ion trap plate 21, respectively, in the superposing direction (direction from the plasma producing chamber 12 toward the wafer processing chamber 13). Each through hole 20c does not overlap each through hole 21c when viewed from the plasma producing chamber 12 toward the wafer processing chamber 13.

The conductors 20a and 21a are made of metal such as aluminum, and the insulating films 20b and 21b are made of, for example, alumite or yttria. It should be noted that the wafer processing chamber 13 side of the lower ion trap plate 21 may be covered with quarts and further have silicon welded thereto. In this case, a DC voltage may be applied to the silicon.

In the ion trap 14, the lower ion trap plate 21 has a plurality of gas outlets 23 (another process gas introducing unit), which are disposed at almost evenly dispersed locations. The plurality of gas outlets 23 introduce a process gas other than the process gas introduced by the process gas introducing unit 16 into the wafer processing chamber 13.

The conductors 20a and 21a of the upper ion trap plate 20 and the lower ion trap plate 21 in the ion trap 14 are grounded, and because the mounting stage 17 to which a bias voltage is applied faces the ion trap 14, the ion trap 14 acts as an opposing electrode for the mounting stage 17 with respect to the bias voltage. Thus, an electric field positively arises from the ion trap 14 toward the mounting stage 17 in the wafer processing chamber 13.

Referring again to FIG. 1, the high-frequency antennas 15 are each comprised of an antenna core material, and, for example, a tube made of quarts covering the antenna core material in the plasma producing chamber 12, and applies high-frequency electrical power to the interior of the plasma producing chamber 12. The high-frequency antennas 15 are disposed at least 30 mm or more away from the ion trap 14. The plurality of high-frequency antennas 15 are disposed at dispersed locations in the plasma producing chamber 12 so that plasma P can be uniformly produced in the plasma producing chamber 12. It should be noted that the tubes of the high-frequency antennas 15 are covered with yttria, for example, so as to prevent corrosion.

When plasma processing is to be carried out on the wafer W in the substrate processing apparatus 10, first, the evacuating unit 19 maintains the pressure in the chamber 11 at 1.3×10⁻³ Pa to 1.3×10⁴ Pa (10⁻⁵ Torr to 100 Torr), and the high-frequency antennas 15 apply high-frequency electrical power with a frequency of, for example, 13.56 MHz into the plasma producing chamber 12, and the process gas introducing unit 16 introduces a process gas into the plasma producing chamber 12. At this time, the introduced process gas is excited by the high-frequency electrical power and turned into high density plasma P with an ion concentration of, for example, about 10¹⁰ cm⁻³ to 10¹¹ cm⁻³. As a high-frequency electrical power application sequence carried out by the plurality of high-frequency antennas 15 so as to generate the plasma P, a desired sequence can be used according to the contents of the plasma processing. For example, all the high-frequency antennas 15 may apply high-frequency electrical power at the same time, or the high-frequency antennas 15 may sequentially apply high-frequency electrical power in a circular pattern in the plasma producing chamber 12. The frequency of the high-frequency electrical power applied by the high-frequency antennas 15 is not limited to 13.56 MHz, and may be 100 KHz to 100 MHz.

The plasma P produced in the plasma producing chamber 12 moves toward the interior of the wafer processing chamber 13 due to gravity and the bias voltage applied to the mounting stage 17. When the plasma P reaches the ion trap 14, electrons in the plasma P are charged to the insulating films 20b and 21b of the upper ion trap plate 20 and the lower ion trap plate 21, and the major portion of the ions in the plasma P are attracted by the charged electrons, so that a sheath 24 is produced in the vicinity of the upper ion trap plate 20 and the lower ion trap plate 21 (see FIG. 2). Namely, because the major portion of the ions in the plasma P remains in the vicinity of the ion trap 14, the number of the ions attracted to the wafer W mounted on the mounting stage 17 can be reduced. Moreover, because the ion trap 14 is interposed between the plasma producing chamber 12 and the wafer processing chamber 13, the ion trap 14 blocks ultraviolet light emitted from the plasma P produced in the plasma producing chamber 12 toward the interior of the wafer processing chamber 13.

The plasma P having passed the ion trap 14 then reaches the wafer W mounted on the mounting stage 17, and carries out the plasma processing on the wafer W.

According to the substrate processing apparatus 10 of the present embodiment, because the ion trap 14 partitions the interior of the chamber 11 into the plasma producing chamber 12 and the wafer processing chamber 13, and the ion trap 14 is comprised of the plate-like upper ion trap plate 20 and lower ion trap plate 21 doubly disposed from the plasma producing chamber 12 toward the wafer processing chamber 13, the intensity of ultraviolet light reaching the wafer W can be positively decreased. Moreover, because the upper ion trap plate 20 and the lower ion trap plate 21 of the ion trap 14 have the insulating films 20b and 21b that cover the surfaces of the conductors 20a and 21a, respectively, the upper ion trap plate 20 and the lower ion trap plate 21 can attract the ions when the plasma P produced in the plasma producing chamber 12 goes toward the wafer processing chamber 13, and the major portion of the ions in the plasma P remains in the vicinity of the ion trap 14. As a result, radicals in the plasma P can be preferentially caused to reach the wafer W. Further, because the ion trap 14 has the grounded conductors 20a and 21a, an electrical field extending from the ion trap 14 toward the mounting stage 17 can be positively produced in the wafer processing chamber 13. As a result, desired plasma processing can be appropriately carried out on the wafer W.

In the substrate processing apparatus 10 described above, the upper ion trap plate 20 and the lower ion trap plate 21 have the plurality of through holes 20c and 21c that penetrate the upper ion trap plate 20 and the lower ion trap plate 21 in the superposing direction, the plasma P can pass the ion trap 14 from the plasma producing chamber 12 toward the wafer processing chamber 13. On the other hand, when viewed from the plasma producing chamber 12 toward the wafer processing chamber 13, the through holes 20c of the upper ion trap plate 20 do not overlap the through holes 21c of the lower ion trap plate 21, and hence ions moving linearly from the plasma producing chamber 12 toward the wafer processing chamber 13 due to the bias voltage collide with the upper ion trap plate 20 or the lower ion trap plate 21 and thus cannot pass the ion trap 14. As a result, radicals in the plasma P can be more preferentially caused to reach the wafer W mounted on the mounting stage 17.

Moreover, the substrate processing apparatus 10 described above further has the plurality of gas jet holes 23, which are disposed at dispersed locations on the wafer processing chamber 13 side of the ion trap 14, the wafer W can be subjected to not only the plasma processing but also processing using other process gas, and thus processing variations can be increased, and also, other process gas can be introduced into the wafer processing chamber 13 in a dispersed manner, and hence processing using other process gas can be evenly carried out on the wafer W.

Further, because in the substrate processing apparatus 10 described above, the distance between the high-frequency antennas 15 and the ion trap 14 is at least 30 mm, the ion trap 14 can be prevented from inhibiting the formation of a magnetic field produced from the high-frequency antennas 15, and hence the plasma P can be efficiently produced in the plasma producing chamber 12.

Moreover, because in the substrate processing apparatus 10, the ion trap 14 is interposed between the plasma producing chamber 12 and the wafer processing chamber 13, a difference between the pressure in the plasma producing chamber 12 and the pressure in the wafer processing chamber 13 can be developed. For example, the pressure in the plasma producing chamber 12 may be set to be higher than the pressure in the wafer processing chamber 13. In this case, a by-product produced in the plasma processing on the wafer W can be prevented from flowing back from the wafer processing chamber 13 into the plasma producing chamber 12 and becoming attached to the high-frequency antennas 15.

Although in the substrate processing apparatus 10 described above, the ion trap 14 is comprised of the upper ion trap plate 20 and the lower ion trap plate 21, the ion trap 14 may be comprised of one or three or more ion trap plates.

Next, a description will be given of a substrate processing method according to the present embodiment.

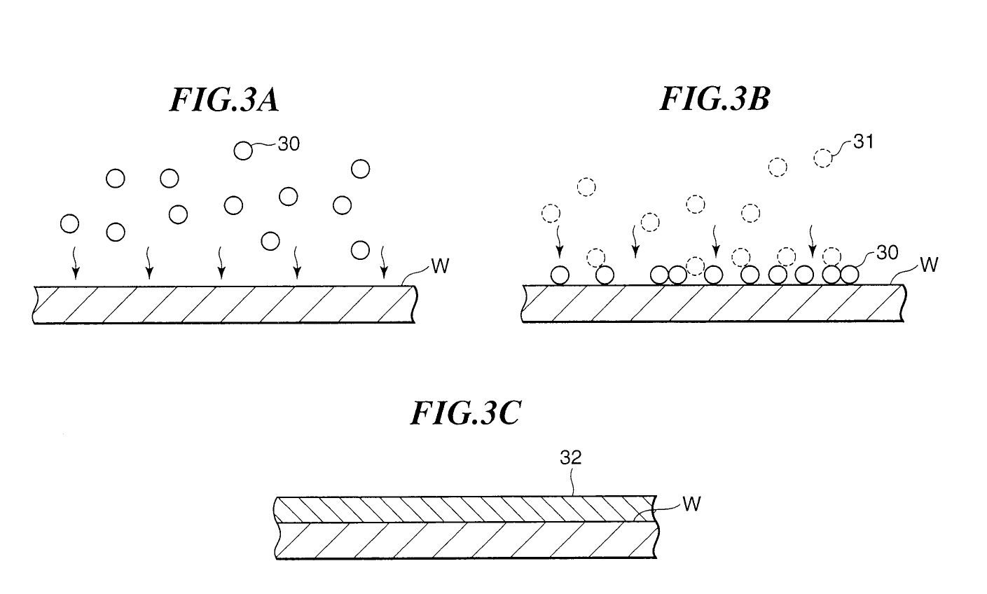

FIGS. 3A to 3C are process drawings showing a film formation method as the substrate processing method according to the present embodiment. In this film formation method, a silicon dioxide film is formed on a surface of the wafer W.

In the substrate processing apparatus 10, first, the wafer W is accommodated in the wafer processing chamber 13 and mounted on the mounting stage 17, and BTBAS (Bis tertial butyl amino silane) 30 as a silane-based gas is introduced from the gas outlets 23 into the wafer processing chamber 13 (raw gas introducing step). The BTBAS 30 is a gas containing a large amount of silicon, and the introduced BTBAS 30 becomes attached to a surface of the wafer W (FIG. 3A).

Then, the introduction of the BTBAS 30 is stopped, oxygen gas is introduced into the plasma producing chamber 12, and high-frequency electrical power is applied into the plasma producing chamber 12 by the high-frequency antennas 15 to produce oxygen plasma (plasma producing step). The produced oxygen plasma moves toward the interior of the wafer processing chamber 13 due to gravity and the bias voltage applied to the mounting stage 17, but the major portion of oxygen ions in the oxygen plasma remains in the vicinity of the ion trap 14 by the ion trap 14, oxygen radicals 31 in the oxygen plasma more preferentially reaches the wafer W (FIG. 3B). At this time, ultraviolet light emitted by the oxygen plasma P in the plasma producing chamber 12 toward the wafer processing chamber 13 is blocked by the ion trap 14.

As a result, a chemical reaction of the silicon and the oxygen radicals 31 can be caused while various films (including a silicon dioxide film being formed) formed on the wafer W can be prevented from deteriorating due to ultraviolet light and unexpectedly wearing due to oxygen ion sputtering, and as a result, a silicon dioxide film 32 can be positively formed on the surface of the wafer W (FIG. 3C).

It should be noted that the raw gas introducing step and the plasma producing step described above may be repeated alternately, which can easily form a silicon dioxide film having a predetermined thickness.

Although in the above described film formation method, the BTBAS is used as the silane-based gas, the silane-based gas is not limited to this, for example, dichlorosilane, hexachlorodisilane, monosilane, disilane, hexamethyldisilazane, tetrachlorosilane, disilyl amine, or trisilyl amine may be used.

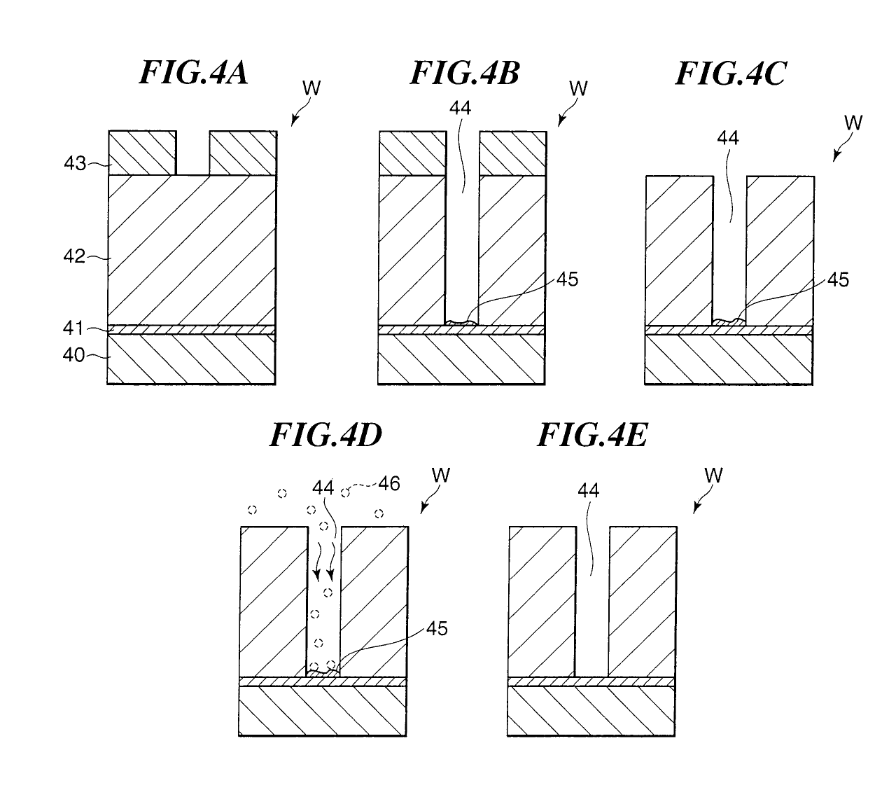

FIGS. 4A to 4E are process drawings showing a dry cleaning method as the substrate processing method according to the present embodiment. In this dry cleaning method, foreign matter deposited on a surface of an NiSi layer that exposes itself when a contact hole for the NiSi layer is formed in a PMD (pre-metal dielectric) film by dry etching is removed.

Conventionally, wet cleaning such as RCA cleaning using a medical solution so as to remove foreign matter on a surface of a layer exposing itself after dry etching is carried out on the wafer W. However, the wet cleaning does poorly promotes a chemical reaction of the medical solution and the foreign matter, and it is thus difficult to completely remove the foreign matter, resulting in a decrease in yields. Moreover, the wet cleaning requires a drying process, which brings about a decrease in throughput. Further, organic films such as Low-k films are expected to be widely used as insulating films in the future, but the organic films absorb the medical solution, and the absorbed medical solution evaporates in subsequent processes, which may adversely affect subsequent processing.

Accordingly, in the present embodiment, the substrate processing apparatus 10 removes foreign matter by dry cleaning using plasma.

First, in a wafer W in which an NiSi layer 41, a PMD layer 42, and a photoresist layer 43 from which the PMD layer 42 is partially exposed are laminated on a silicon substrate 40 in this order (FIG. 4A), the PMD layer 42 is etched by dry cleaning to form a contact hole 44 from which the NiSi layer 41 is partially exposed. At this time, foreign matter 45 composed mainly of reaction product produced during the dry etching is deposited on a surface of the NiSi layer 41 exposed at the bottom of the contact hole 44 (FIG. 4B).

Then, the photoresist layer 43 is removed by ashing using oxygen plasma (FIG. 4C). At this time as well, reaction product produced during the ashing is further deposited as foreign matter 45.

Then, in the substrate processing apparatus 10, the wafer W is accommodated in the wafer processing chamber 13 and mounted on the mounting stage 17, hydrogen gas is introduced into the plasma producing chamber 12, and high-frequency electrical power is applied into the plasma producing chamber 12 by the high-frequency antennas 15 to produce hydrogen plasma (plasma producing step). The produced hydrogen plasma moves toward the interior of the wafer processing chamber 13 due to gravity and the bias voltage applied to the mounting stage 17, but the major portion of hydrogen ions in the hydrogen plasma remains in the vicinity of the ion trap 14 by the ion trap 14, and hence hydrogen radicals 46 in the hydrogen plasma preferentially reach the wafer W (FIG. 4D).

Thus, the foreign matter 45 can be preferentially caused to chemically react with the hydrogen radicals 46 without being sputtered by the hydrogen ions. At this time, the hydrogen radicals 46 remove the foreign matter 45 by turning the foreign matter 45 into reaction product through a chemical reaction and causing the same to sublime (FIG. 4E). Moreover, because the major portion of the hydrogen ions does not reach the wafer W, wear of other films formed from substance that do not react with the hydrogen radicals 46 can be prevented. Further, the hydrogen radicals 46 are active species and promote the chemical reaction of the foreign matter 45, and hence the hydrogen radicals 46 can almost completely remove the foreign matter 45. Also, because the foreign matter 45 is removed using the chemical reaction, the chemical reaction with the hydrogen radicals 46 automatically ends if the foreign matter 45 as an object of the chemical reaction with the hydrogen radicals 46 is removed, and hence wear of other films can be automatically prevented.

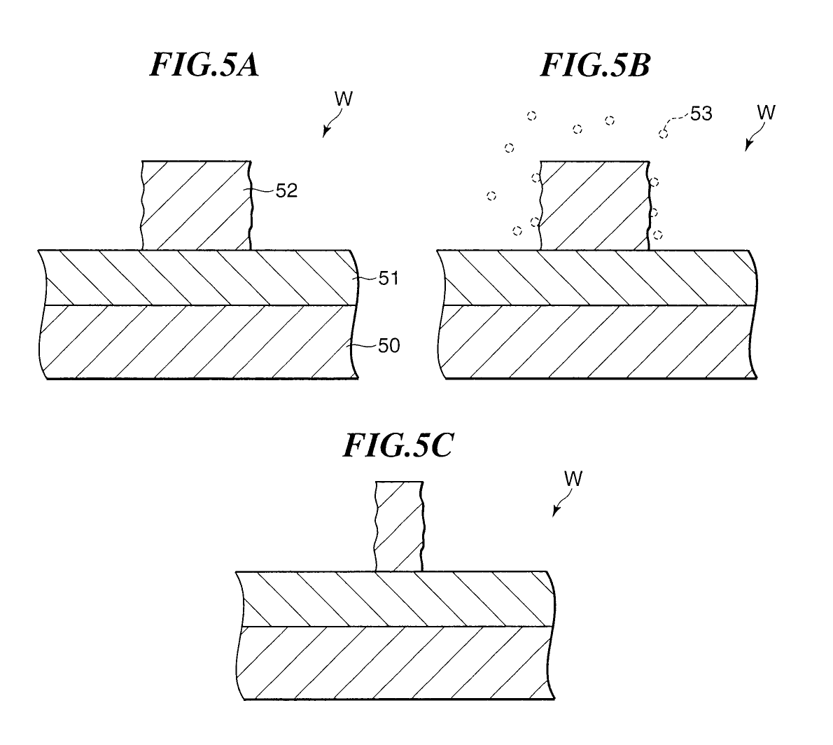

FIGS. 5A to 5C are process drawings showing a trimming method as the substrate processing method according to the present embodiment. In this trimming method, a width of a projection comprised of a developed photoresist is reduced (trimmed) using a strong alkaline solution.

In general, when a mask film comprised of a photoresist with a predetermined pattern is to be developed on a wafer using a photoresist, first, a photoresist is coated on the entire surface of the wafer by a spin coater to form a photoresist film, and then ultraviolet light with a reversal pattern of a predetermined pattern is irradiated onto the photoresist film, so that a part of the photoresist film corresponding to the reversal pattern is altered to be alkali soluble, and further, the altered part of the photoresist film is removed by the strong alkaline solution.

In recent years, a width of a trench formed on a wafer has been decreasing to 20 nm or less with miniaturization of semiconductor devices. On the other hand, a width of a trench cannot be 50 nm or less only by development of a mask film using a conventional stepper, and hence at present, after a mask film comprised of a photoresist film is developed using a stepper, and then a projection of the mask film is etched by oxygen plasma so that the width of the projection can be reduced.

However, in the conventional etching using oxygen plasma, not only oxygen radicals but also oxygen ions reach the mask film. In general, directionless oxygen radicals isotropically etch the projection, whereas oxygen ions etch the projection by sputtering the same in the direction of height because the direction of movement of oxygen radicals depends on a bias voltage. Thus, when a desired width of the projection is obtained by the etching using the oxygen plasma, the height of the projection is too small, and the projection may not act as a mask film.

To cope with this, in the present embodiment, the substrate processing apparatus 10 preferentially causes a projected photoresist of a mask film to chemically react with oxygen radicals so that the width of the projection can be reduced.

First, a wafer W in which an SiN layer 50, a BARC layer 51, and a projection 52 comprised of a photoresist from which the BARC layer 51 is partially exposed are laminated in this order (FIG. 5A) is accommodated in the wafer processing chamber 13 and mounted on the mounting stage 17, oxygen gas is introduced into the plasma producing chamber 12, and high-frequency electrical power is applied into the plasma producing chamber 12 by the high-frequency antennas 15 to produce oxygen plasma (plasma producing step). The produced oxygen plasma moves toward the interior of the wafer processing chamber 13 due to gravity and the bias voltage applied to the mounting stage 17, but the major portion of the oxygen ions in the oxygen plasma remains in the vicinity of the ion trap 14 by the ion trap 14, and hence oxygen radicals 53 in the oxygen plasma preferentially reach the wafer W (FIG. 5B).

By the way, the side surface of the projection 52 is a boundary with an area where the photoresist alters to be alkali soluble, and is exposed to a strong alkaline solution when the mask film is developed, and hence its texture becomes chemically weak. Thus, the directionless oxygen radicals 53 selectively etch the side surface of the projection 52 through a chemical reaction. Also, the major portion of the oxygen ions does not reach the projection 52, and hence the projection 52 is hardly sputtered by the oxygen ions.

Further, because the photoresist may shrink due to ultraviolet light, the projection 52 may shrink in the direction of height due to ultraviolet light emitted from the oxygen plasma in the plasma producing chamber 12 toward the wafer processing chamber 13, but in the substrate processing apparatus 10, ultraviolet light emitted by oxygen plasma in the plasma producing chamber 12 is blocked by the ion trap 14, and therefore, the projection 52 never shrinks in the direction of height.

As a result, the width of the projection 52 can be reduced without making the height of the projection 52 too small (FIG. 5C).

It should be noted that the inventors of the present invention reduced the width of the projection 52 having a predetermined width using the trimming method described above, and ascertained that an aspect ratio of the projection 52 increases as trimming progresses (for example, the aspect ratio is 3.6 upon the lapse of a trimming time period of 7 seconds, the aspect ratio is 4.0 upon the lapse of a trimming time period of 14 seconds, and the aspect ratio is 4.2 upon the lapse of a trimming time period of 21 seconds). Namely, it was found that by using the trimming method described above, the width of the projection 52 can be reduced without making the height of the projection 52 too small.

Although in the above described present embodiment, the substrates to be used are semiconductor wafers, the substrate to be used are not limited to them and rather may instead be any of various glass substrates used in LCDs (Liquid Crystal Displays), FPDs (Flat Panel Displays), or the like.

What is claimed is:

1. A substrate processing apparatus comprising:
an accommodating chamber in which a substrate is accommodated;
a partition member that partitions said accommodating chamber into a plasma producing chamber and a substrate processing chamber;
high-frequency antennas disposed in the plasma producing chamber;
a process gas introducing unit that introduces a process gas into the plasma producing chamber; and
a mounting stage that is disposed in the substrate processing chamber, and on which the substrate is mounted and to which a bias voltage is applied,
wherein said partition member comprises grounded conductors and insulating materials covering surfaces of said conductors.

2. A substrate processing apparatus as claimed in claim 1, wherein said partition member comprises plate-like members that are at least doubly disposed from the plasma producing chamber toward the substrate processing chamber, and said plate-like members comprise insulating materials covering surfaces.

3. A substrate processing apparatus as claimed in claim 2, wherein the plate-like members comprise a plurality of through holes penetrating the plate-like members in a superposing direction, and
when viewed from the plasma producing chamber toward the substrate processing chamber, the through holes of one of the plate-like members do not overlap the through holes of the other one of the plate-like members.

4. A substrate processing apparatus as claimed in claim 1, further comprising another process gas introducing unit that introduces another process gas into the substrate processing chamber.

5. A substrate processing apparatus as claimed in claim 4, wherein said other process gas introducing unit comprises a plurality of gas outlets, and the plurality of gas outlets are disposed at dispersed locations on the substrate processing chamber side of said partition member.

6. A substrate processing apparatus as claimed in claim 1, wherein a distance between said high-frequency antennas and said partition member is 30 mm or more.

7. A substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, a mounting stage that is disposed in the substrate processing chamber, and on which the substrate is mounted and to which a bias voltage is applied, and another process gas introducing unit that produces another process gas into the substrate processing chamber, the partition member comprising grounded conductors and insulating materials covering surfaces of the conductors, comprising:
a raw gas introducing step in which the other process gas introducing unit introduces a silane-based gas into the substrate processing chamber; and
a plasma producing step in which the process gas introducing unit introduces oxygen gas into the plasma producing chamber, and the high-frequency antennas produce plasma from the oxygen gas.

8. A substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, and a mounting stage that is disposed in the substrate processing chamber, and on which the substrate is mounted and to which a bias voltage is applied, the partition member comprising grounded conductors and insulating materials covering surfaces of the conductors, comprising:
a plasma producing step in which the process gas introducing unit introduces hydrogen gas into the plasma producing chamber, and the high-frequency antennas produce plasma from the hydrogen gas,
wherein foreign matter is deposited on at least a part of a surface of the substrate.

9. A substrate processing method executed by a substrate processing apparatus comprising an accommodating chamber in which a substrate is accommodated, a partition member that partitions the accommodating chamber into a plasma producing chamber and a substrate processing chamber, high-frequency antennas disposed in the plasma producing chamber, a process gas introducing unit that introduces a process gas into the plasma producing chamber, and a mounting stage that is disposed in the substrate processing chamber, and on which the substrate is mounted and to which a bias voltage is applied, the partition member comprising grounded conductors and insulating materials covering surfaces of the conductors, comprising:
a plasma producing step in which the process gas introducing unit introduces oxygen gas into the plasma producing chamber, and the high-frequency antennas produce plasma from the oxygen gas,
wherein the substrate has on a surface thereof a projection that comprises a photoresist and having a predetermined width.
